(19) United States
(12) Patent Application Publication
(10) Pub. No.: US 2026/0098883 A1
(43) Pub. Date: Apr. 9, 2026

(54) CHARACTERIZATION OF ELECTROCHEMICAL CELLS

(71) Applicant: Cirrus Logic International Semiconductor Ltd., Edinburgh (GB)

(72) Inventors: John P. LESSO, Edinburgh (GB); Claire MOTION, Edinburgh (GB); James T. DEAS, Edinburgh (GB)

(73) Assignee: Cirrus Logic International Semiconductor Ltd., Edinburgh (GB)

(21) Appl. No.: 18/909,370

(22) Filed: Oct. 8, 2024

(51) Int. Cl. G01R 27/16; G01N 27/416

(52) U.S. Cl. CPC G01R 27/16; G01N 27/4163

(57) ABSTRACT

Circuitry for determining a characteristic of an electrochemical cell having a first electrode and a second electrode, the circuitry comprising: a first capacitor node and a second capacitor node for coupling of a series capacitor therebetween, the first capacitor node for coupling to the working electrode; drive circuitry coupled to the second capacitor node, the drive circuitry configured to apply a first time-varying stimulus to the first electrode via the series capacitor; measurement circuitry configured to determine a sense signal derived from a sense current at the first electrode and output the sense signal at an output of the measurement circuitry; and processing circuitry configured to determine a characteristic of the electrochemical cell based on the sense signal.

### TECHNICAL FIELD

The present disclosure relates to circuitry and methods for measuring characteristics in electrochemical cells.

### BACKGROUND

Electrochemical sensors are widely used for the detection or characterisation of one or more particular chemical species, analytes, typically as an oxidation or reduction current. Such sensors comprise an electrochemical cell, consisting of two or more electrodes configured for contact with an analyte whose concentration is to be ascertained.

For potentiostatic measurement typically used for characterisation of potentiostatic cells, sensors may comprise circuitry for driving one or more of the electrodes and circuitry for measuring a response signal at one or more of the electrodes. The measured response signal can be processed to determine a concentration of an analyte.

For potentiometric measurement typically used for characterisation of ion-selective electrode (ISE) sensors, a potential difference is measured between two electrodes separated by an analyte with no external bias and with no current flow. A working electrode (indicator electrode) of the electrochemical cell can be used as a proxy for the electrode, and a reference electrode can be used as a proxy for the analyte. Thus, the potential difference between the working electrode and the reference electrode gives an indication of a property of the electrode and the analyte.

An electrode such as an ISE can decay or degrade with significant impedance changes due to reactions between the environment (such as a human body) to the presence of the electrode. This decay can negatively impact any coating provided on the electrode causing drift in measurements obtained from the ISE. To limit such decay and drift, it may be advantageous to minimize Faradaic reactions at the ISE.

### SUMMARY

According to a first aspect of the disclosure, there is provided circuitry for determining a characteristic of an electrochemical cell having a first electrode and a second electrode, the circuitry comprising: a first capacitor node and a second capacitor node for coupling of a series capacitor therebetween, the first capacitor node for coupling to the working electrode; drive circuitry coupled to the second capacitor node, the drive circuitry configured to apply a first time-varying stimulus to the first electrode via the series capacitor; measurement circuitry configured to determine a sense signal derived from a sense current at the first electrode and output the sense signal at an output of the measurement circuitry; and processing circuitry configured to determine a characteristic of the electrochemical cell based on the sense signal.

The characteristics may comprise one or more of: an impedance; and an analyte concentration.

The processing circuitry may comprise: a subtractor configured to subtract the time-varying stimulus from the sense signal and output an intermediate sense signal; and compensation circuitry configured to apply compensation to the intermediate sense signal based on a characteristic of the series capacitor and output a compensated sense signal.

Applying compensation may comprise differentiating the intermediate sense signal.

The measurement circuitry may comprise: a first input coupled to the second capacitor node; and a second input. The drive circuitry may be configured to apply the first time-varying stimulus at the second input.

The measurement circuitry may comprise a transimpedance amplifier, TIA, comprising: an op-amp, wherein the first input comprises an inverting input of the op-amp, the second input comprises a non-inverting input of the op-amp, and the output comprises an output of the op-amp; and a feedback impedance coupled between the output and the first input.

The drive circuitry may be configured to apply a bias voltage at the second input. The bias voltage may be set to half a supply voltage of the TIA.

The measurement circuitry may comprise a current conveyor, CC, wherein first input is an X input of the CC, the second input is a Y input of the CC, and the output is a Z output of the CC.

The measurement circuitry may comprise a first input coupled to the first capacitor node, the sense current measured at the first capacitor node.

The drive circuitry may comprise: a digital to analog converter, DAC, configured to output the first time-varying stimulus based on a digital input signal.

The measurement circuitry may comprise: an amplifier having a first amplifier input and an amplifier output, the amplifier input coupled to the first input of the measurement circuitry; and an impedance coupled between the first amplifier input and a reference voltage.

The amplifier may comprise a second amplifier input, the second amplifier input coupled to the amplifier output.

The measurement circuitry may further comprise: a switch coupled between the first amplifier input and the reference voltage, the switch configured to selectively bypass the impedance.

The processing circuitry may be configured to: determine a first value of the characteristic of the cell based on a DC component of the sense signal; and determine a second value of the characteristic of the cell based on an AC component of the sense signal.

Determining the characteristic of the cell may comprise fusing the first and second values.

The processing circuitry may be configured to: determine the second value of the characteristic based on the AC component in response to a change in the first value of the characteristics of the cell over time.

The processing circuitry may be configured to determine the first value and the second value periodically, the second value being determined more often than the first value.

The processing circuitry may comprise: an analog-to-digital converter, ADC, configured to output a digital sense signal based on the sense signal.

The first electrode or the second electrode may comprise an ion-selective electrode.

The sense signal may comprise a sense voltage or a sense current.

The circuitry may further comprise the series capacitor. The series capacitor may have a capacitance less than an intrinsic capacitance of the first electrode or the second electrode. The series capacitor may have a capacitance smaller than a double-layer capacitance of the electrochemical cell. The series capacitor may have a capacitance at least an order or magnitude smaller than a double-layer capacitance of the electrochemical cell.

A capacitance of the series capacitor may be variable. For example, the circuitry may further comprise one or more switch networks of capacitor multipliers to vary the capacitance of the series capacitor.

According to another aspect of the disclosure, there is provided an electrochemical sensor, comprising: circuitry described above; and the electrochemical cell.

The first electrode may be a working electrode and the second electrode may be a reference electrode.

The first electrode may be an anode and the second electrode may be a cathode

According to another aspect of the disclosure, there is provided a multi-analyte sensor, comprising: circuitry as described above; and the electrochemical cell. The first electrode may be a first ion selective electrode, the second electrode may be a reference electrode, and the electrochemical cell may further comprise a second ion selective electrode.

According to another aspect of the disclosure, there is provided an electronic device, comprising circuitry or sensor as described above.

The electronic device may comprise one of an analyte monitoring device or an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

According to another aspect of the disclosure, there is provided a method of determining a characteristic of an electrochemical cell having a first electrode and a second electrode, the method comprising: applying a first time-varying stimulus to the first electrode via a series capacitor; measuring a sense current derived from the first electrode, the sense current induced by the first time-varying stimulus; determining a sense signal based on the measured sense current; and determining a characteristic of the electrochemical cell based on the sense signal.

Throughout this specification the word “comprises”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 illustrates a schematic symbol and diagram of an electrochemical cell comprising an ion-selective electrode;

FIG. 2 is a schematic diagram of a known measurement circuit;

FIGS. 3 to 5 are schematic diagrams of drive and measurement circuitry;

FIG. 6 is a graphical illustration comparing sense voltage with and without a series capacitor;

FIGS. 7 and 8 are equivalent Thevenin models for the cell of FIG. 1 with and without a series capacitor; and

FIGS. 9 to 12 are schematic diagrams of drive and measurement circuits.

### DESCRIPTION OF EMBODIMENTS

Embodiments of the present disclosure relate to the measurement of signals (such as analyte signals) in electrochemical cells comprising an ion-selective electrode (ISE). In particular, embodiments relate to improved methods of reducing drift due to Faradaic reactions in a cell comprising an ISE by providing a capacitor in series with the cell. In addition, to address the DC blocking characteristic of such series capacitor, a novel circuit configuration is employed and an AC stimulus is used to derive the impedance at a frequency that scales with concentration, such that the concentration can be measured indirectly.

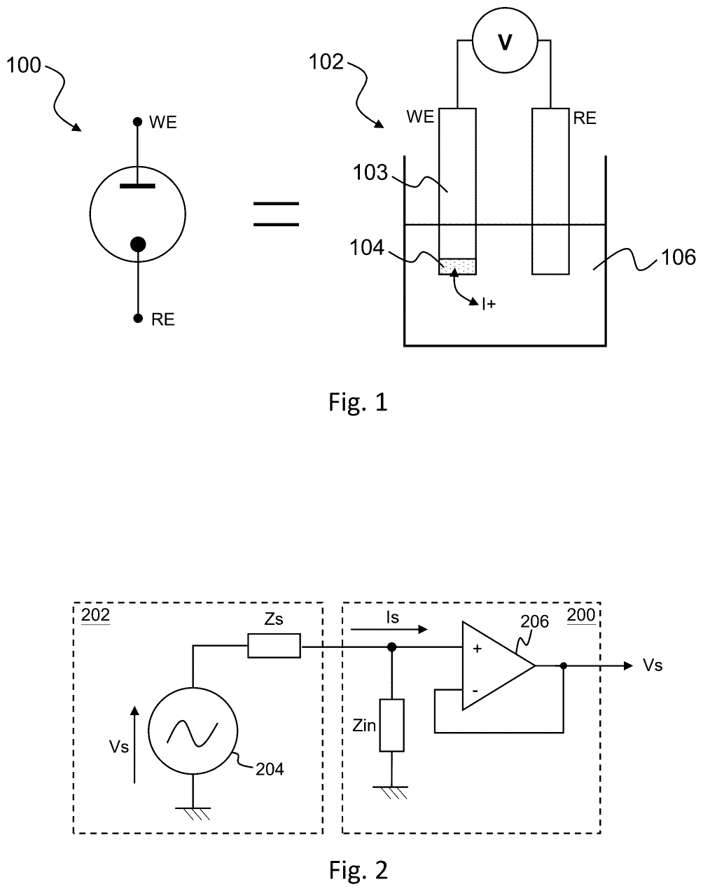

FIG. 1 illustrates an electrochemical cell 100 typically configured for potentiometric sensing alongside a schematic diagram of an example implementation of the electrochemical cell 100 as a potentiometric sensor. The cell 100 comprises a working electrode WE and a reference electrode RE. The working electrode WE comprises an ion-selective electrode 103 having an ion-selective membrane 104, which may be configured to uptake only a specific ion (in this case the cation, I+) from an electrolyte solution 106. As such, the potential difference between the working electrode WE and the reference electrode RE depends on the concentration of that particular ion analyte in the electrolyte solution 106.

To accurately measure the potential difference across the cell 100, as little as possible current (ideally no current) flows into the cell 100. Hence, a typical approach to voltage measurement is to couple each of the working and reference electrodes WE, RE to high input impedance buffers which are used, in turn, to drive one or more ADCs (e.g. two single ended ADCs or one differential ADC). A digital output signal is then derived which represents the potential difference between working and reference electrode WE, RE of the cell 100.

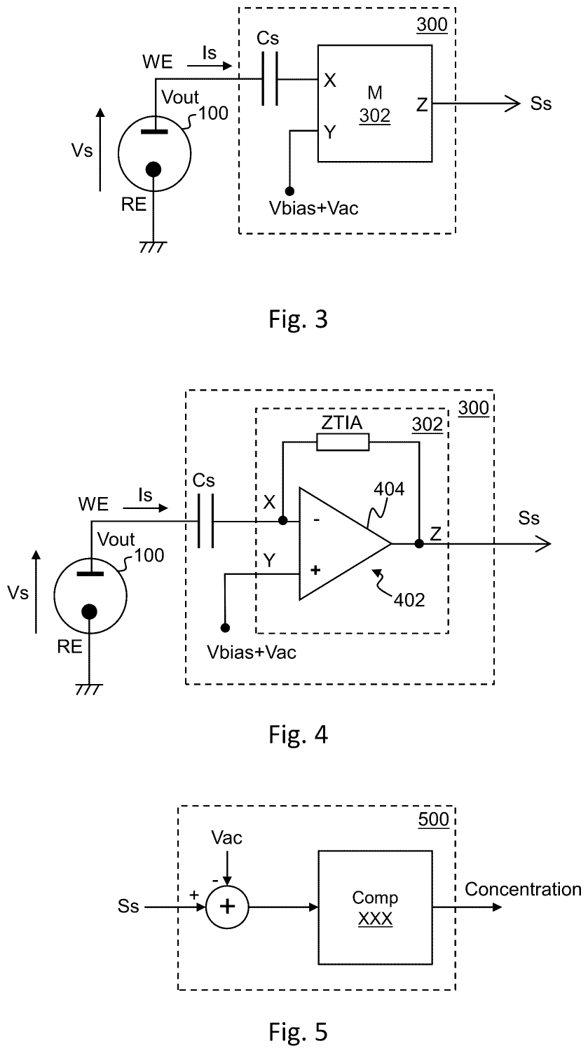

FIG. 2 is a schematic diagram of a typical measurement circuit 400 for measuring a potential difference Vs across the two-electrode cell 100 implemented as a potentiometric sensor. An equivalent circuit model 202 for the cell 100 is shown in FIG. 2. The model comprises a voltage source 204 (generating the potential difference or sense voltage Vs) and a series impedance Zs coupled. The voltage source 204 is coupled between a reference voltage (in this case ground) and the series impedance Zs which itself is coupled to an input of the measurement circuit 200. The measurement circuit 200 comprises a buffer amplifier 206 and an input impedance Zin. A non-inverting input of the buffer amplifier 206 is coupled to the series impedance Zs of the cell 100. The input impedance Zin is coupled between the non-inverting input of the buffer amplifier 206 and a reference voltage (in this case ground). An inverting input and output of the buffer amplifier 206 are coupled together. Thus, the measurement circuit 200 is configured as a high input impedance buffer amplifier which buffers the sense voltage Vs across the cell 100 to the output of the measurement circuit 200.

The input impedance Zin of the measurement circuit 200 is typically an order of magnitude higher than the series impedance Zs of the cell 100. With electrochemical sensors typically having an impedance in the gigaohm range (e.g. 1-10 GΩ), this can lead to the measurement circuit 200 having an input impedance Zs in the order of teraohms (e.g. 1-10 TΩ). To operate at such high input impedance, the measurement circuit 200 is required to have low leakage to avoid drift in the sensed voltage Vs. Such operation can lead to large circuit area. In attempting to select an appropriate impedance level, the impedance needs to be high enough to receive a useful signal, but not so high that leakage and/or noise saturates the circuit front-end. Additionally, synthesizing the required input impedance Zin can require either active circuitry or complex process options which can lead to added cost and complexity. Despite such efforts, the circuit 200 tends to show undesirable temperature dependence.

Thus, there are several problems with the use of high input impedance measurement circuitry of potentiometric sensing:
Calibration: It is desirable to convert measured voltage into a concentration of an analyte present in the cell 100. However, the measured output voltage Vs is a sum of the voltage difference between the Reference Electrode (RE) and the Working Electrode (WE), both of which can evolve differently in time.
Selectivity: Selectivity describes how much of the sense voltage Vs is due to the ion of interest versus an interfering ion. For example, sodium (Na) and potassium (K) ions are relatively similar which can present selectivity challenges. Improved selectivity to just the ion of interest is desirable. Due to different diffusion time constants for each ion, the impedance of the cell 100 will respond differently at different frequencies.
Noise/Drift: A variety of noise sources exist, including drift, which lead to errors in measured DC voltage and hence inferred concentration levels. For example, low frequency noise (e.g. drift) which is due to 1/f\hat{ }n noise in the measurement circuitry and in the sensor/cell 100. Additionally, leakage currents can give rise to noise due to the high input impedance. Small leakage currents give rise to large voltages relative to the signal level. Sensitivity to leakage is a large problem for wearable sensors, as high moisture environments (e.g. when in a bath or shower) are a common use case. The high impedance of the sensor also causes coupling issues and common mode settling problems. Finally, Faradaic reactions in the ISE of the cell 100 can also lead to significant drift over time, as will be explained in more detail below.

Referring again to FIG. 1, the interface between the ISE 103 and the ion-selective membrane (ISM) 104 is prone to undesired redox reactions due to the intrinsic properties of the materials involved and the electrochemical environment they operate in. Conducting polymers and other solid-contact materials typically used in ISEs are chosen for their ability to efficiently transduce ionic activity into an electrical signal. However, these materials also tend to have redox-active sites that can participate in Faradaic processes. When an ISM is in contact with these redox-active materials, electrochemical reactions, such as oxidation and reduction, can occur at the interface. These reactions lead to the continuous flow of charge, resulting in potential drift and signal instability over time. Furthermore, environmental factors, such as the presence of oxygen or other contaminants, can exacerbate these redox processes, further degrading the performance of the electrode. Parasitic redox reactions at the interface of the ISE and the ISM 104 originate from several sources and types of reactions. These undesirable reactions primarily stem from the inherent properties of the materials used and environmental factors. The solid-contact materials, such as conducting polymers (e.g. PEDOT), often contain redox-active sites that can participate in unwanted oxidation and reduction processes. These redox sites can undergo reactions with dissolved oxygen, water, or other redox-active species present in the solution, leading to a continuous flow of electrons and subsequent potential drift. Additionally, impurities or contaminants at the interface, such as metal ions or organic compounds, can also catalyse redox reactions, further contributing to the instability of the cell 100. Environmental factors, including light exposure and pH fluctuations, can accelerate these reactions, causing significant degradation of electrode performance over time. The combined effect of these parasitic reactions is the introduction of noise, potential drift, and reduced reliability of measurements using the cell 100.

Embodiments of the present disclosure aim to address or at least ameliorate one or more of the above issues of sensor drift by providing a series capacitor between the cell 100 and measurement circuitry used to obtain measurements from the cell 100. It has been found that doing so provides an effective strategy for mitigating undesired redox reactions, thereby substantially reducing sensor drift. The series capacitor provides a store of excess charge to suppress such redox reactions, improving performance of the cell 100.

Whilst the provision of a series capacitor addresses the issue of drift, the implementation of such configurations leads to an additional, reconstruction issue. Since the series capacitor blocks direct current (DC), only changes in analyte concentration (or a change in voltage measured across the cell) are detectable by the measurement circuitry. This means that absolute values of sense voltage cannot be established.

Accordingly, the inventors have devised a method of indirect measurement of analyte concentration which combines the provision of a series capacitor with the application of a time-varying (e.g. alternating current (AC)) stimulus to measure impedance at a frequency that scales with concentration. In doing so, a value of cell impedance or analyte concentration, can be established.

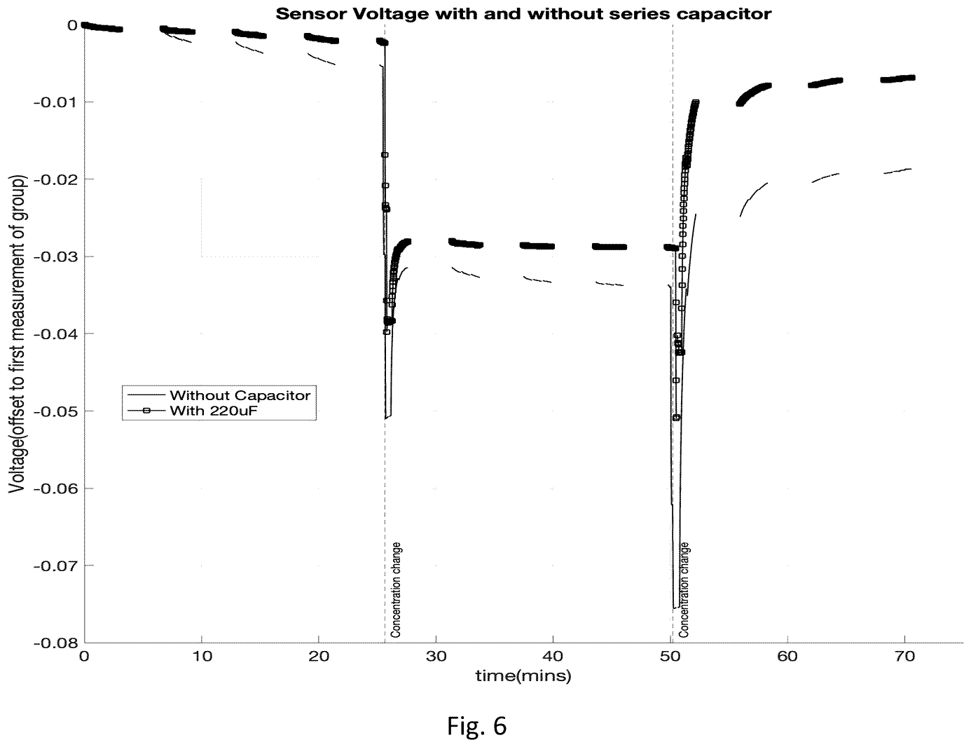

FIG. 3 is a schematic diagram of an example implementation of circuitry 300 for characterising the cell 100 according to embodiments of the present disclosure.

The circuitry 300 comprises a series capacitor Cs and measurement circuitry 302. The series capacitor Cs is coupled between the working electrode WE (e.g. the ISE 103) and a first input X of the measurement circuitry 302. The reference electrode RE of the cell 100 is coupled to a reference voltage, in this case ground GND.

The measurement circuitry 302 further comprises a second input Y and an output Z. The second input is coupled to a drive voltage Vd which consists of a bias voltage Vbias and an time-varying (AC) stimulus Vac. The measurement circuitry 302 is configured to maintain the voltage at the first input X equal to the voltage at the second input Y. As such, by applying an AC stimulus Vac to the second input Y, that AC stimulus is reflected at the first input X and thus applied at the working electrode WE of the cell 100 via the series capacitor Cs. Any time-varying (AC) response of the cell 100 invoked by the AC stimulus is coupled through the series capacitor Cs to the first input X. The measurement circuitry 302 is further configured to output at the output Z a sense signal Ss proportional to a current flowing at the first input X. Thus, any such AC response will be reflected in the sense signal Ss at the output Z of the measurement circuitry 302.

Thus, to measure an impedance of the cell 100, an AC stimulus may be applied at the second input Y, which is in turn injected into the cell 100. The cell 100 will then exhibit an AC response measurable in the sense current Is which is coupled across the series capacitor Cs to the first input X. An AC component of the sense signal Ss output at the output Z of the measurement circuitry 302 can then be processed to determine the impedance of the cell 100.

The AC stimulus applied at the second input Y may comprise one or more sine waves, one or more square waves, or a combination of sine and square waves. Additionally, or alternatively, the AC stimulus may comprise a chirp. The frequency of components of the AC stimulus may be selected to interrogate the cell 100 at one or more frequencies of interest. Such frequencies of interest may be chosen to maximise changes in impedance of the cell 100 in response to changes in concentration of an analyte of interest. Such frequencies of interest may be determined empirically. Additionally, or alternatively, such frequencies of interest may be determined by other measurements performed at the cell 100.

As noted above, the measurement circuitry 302 is configured to establish on its first input X a voltage equal to the voltage provided to its second input Y. An example component which exhibits this characteristic includes a current conveyor (CC). A current conveyor (CC) is able to buffer an input current to its output Z whilst maintaining a voltage at its first input X equal to a voltage applied to its second input Y. Another example of a circuit element which exhibits such a characteristic is a transimpedance amplifier (TIA). When the measurement circuitry 302 is implemented as a TIA, a voltage at its output Z may be representative of an input current at its first input X.

FIG. 4 illustrates an implementation of the circuitry 300 in which the measurement circuitry 302 comprises a TIA 402 comprising an operational amplifier (op-amp) 404 with a feedback impedance ZTIA coupled between an inverting input and output of the op-amp 404. A non-inverting input of the op-amp 404 is coupled to the second input Y of the measurement circuitry 302 and in turn the drive voltage Vd (Vbias+Vac). In some embodiments, the bias voltage Vbias is set to half a supply voltage Vdd, i.e. Vref=Vdd/2, which allows for easier design of the TIA 402. The inverting input of the op-amp 404 is coupled to the first input X of the measurement circuitry 302. Thus, the TIA 402 is configured to output at the output Z of the measurement circuitry 302 a voltage as the sense signal Ss which is proportional to the AC component of the sense current Is at the working electrode WE.

In a variation of the arrangement shown in FIG. 4, the TIA 402 may be replaced with a current conveyor (CC). In which case, the sense signal Ss output from the current conveyor is a current.

It will be appreciated that to obtain an absolute measurement of cell impedance, compensation must be applied to the sense signal Ss to compensate for the AC stimulus injected into the cell 100. Accordingly, referring to FIG. 3, the circuitry 300 may comprise processing circuitry to apply compensation to the sense signal Ss to obtain a measurement if impedance of the cell 100.

FIG. 5 illustrates example processing circuitry 500 which may be incorporated into the circuitry 300 of FIG. 3 for compensating the sense signal Ss output from the measurement circuitry 302. The processing circuitry 500 comprises a subtractor 502 and compensation circuitry 504. The sense signal Ss is provided to the subtractor 502 which subtracts the AC stimulus Vac from the sense signal Ss. The AC stimulus Vac is the same as that which is applied to the second input Y of the measurement circuitry 302. The subtractor 502 outputs an intermediate signal Si, with the AC stimulus removed, to the compensation circuitry 504.

The compensation circuitry 504 may compensate out the effect of the external capacitor Cext. The integrating behaviour of the external capacitor Cext may be addressed by applying a high-pass filter (e.g. a differentiator). The compensation circuitry 504 may differentiate the intermediate signal Si to obtain an absolute value of impedance of the cell 100 which corresponds to an analyte concentration in the cell 100. The compensation circuitry 504 may implement least squares differentiation. The compensation circuitry 504 may be configured to implement low pass filtering to avoid differentiating (or gaining the noise of) high frequency signals. The low-pass filtering may be implemented using a shelving filter.

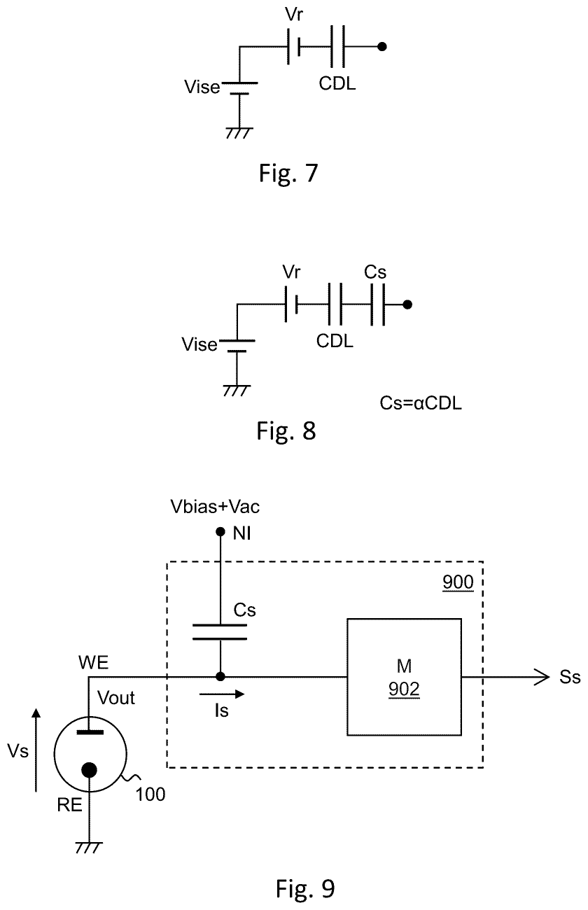

The effect of providing a series capacitor Cs in series with the cell 100 for measurement purposes will now be described graphically and empirically with reference to FIGS. 6 to 8.

FIG. 6 graphically illustrates the effect of providing the series capacitor Cs in series with the cell 100. FIG. 6 graphically illustrates respective sense signals (in this case voltages) over time obtained with and without the series capacitor Cs. Responses in respective sense signals to changes in analyte concentration can be seen at around 26 minutes and around 50 minutes. It can be seen that without the series capacitor Cs, the sense voltage drifts substantially more than with the series capacitor Cs present.

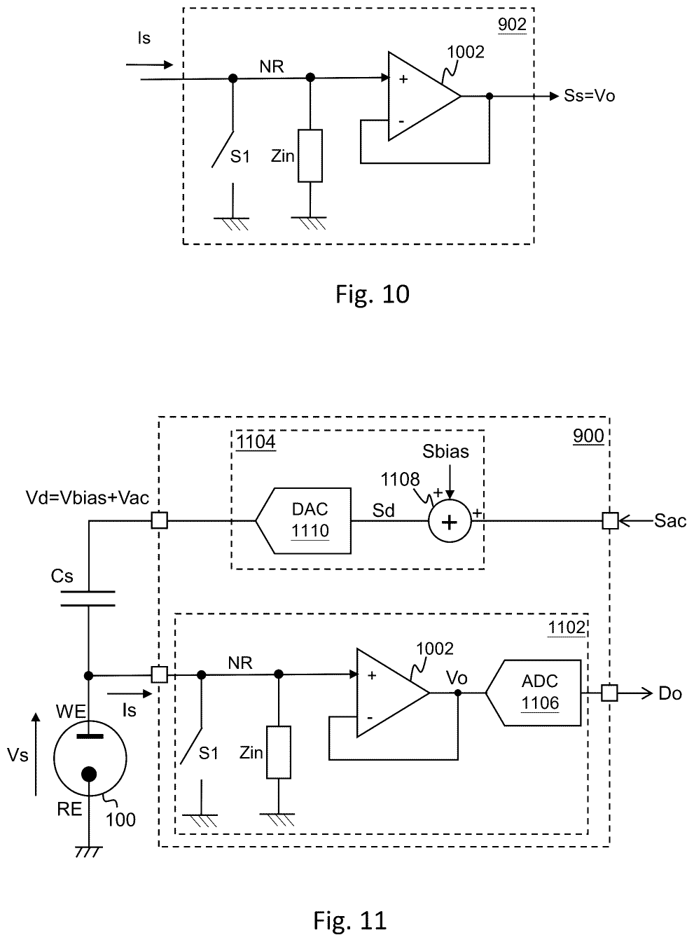

FIG. 7 illustrates an equivalent Thevenin model for the cell 100 and FIG. 8 illustrates the equivalent Thevenin model for the cell 100 in series with the series capacitor Cs. Vise represents the potential associated with the ISE 103. Vr represents potential due to redox reactions.

For the circuit of FIG. 7, where CDL is the double layer capacitance, the double layer charge QDL is given by:

$$\begin{matrix}{Q}_{D L} = {C}_{D L} ( {V}_{ISE} + {V}_{R} ) \\ \frac{d {Q}_{D L}}{d {V}_{R}} = {C}_{D L}\end{matrix}$$

For the circuit of FIG. 8, the total capacitance CT is given by:

$$\begin{matrix}{C}_{T} = {C}_{D L} \frac{α}{1 + α} \\ \frac{d {Q}_{D L}}{d {V}_{R}} = {C}_{D L} \frac{α}{1 + α}\end{matrix}$$

To mimic the effect of redox reactions, the external capacitance may be chosen such that:

$$\begin{matrix}Cs = {αC}_{D L} \\ α < 1\end{matrix}$$

In doing so, the voltage Vise is attenuated, making potentiometric measurement more difficult.

A capacitance of the series capacitor Cs may be chosen such that the series capacitor Cs dominates the overall capacitance of the system. For example, the series capacitor Cs may be provided with a capacitance smaller than the intrinsic capacitance of the ISE 103, such that the overall system capacitance becomes governed by this series capacitor Cs. Such an arrangement forces the system to behave more like an ideal capacitor, characterised by rapid charge and discharge cycles that quickly return to a baseline state. This ideal capacitive behaviour ensures that the current transient decay swiftly to zero, minimising the influence of slower, continuous Faradaic processes that would otherwise cause potential drift. Such stabilisation leads to improved consistency and reliability in the signal provided to the measurement circuitry 302.

In some embodiments, a value of the series capacitor Cs may be varied dynamically, for example to achieve optimal settling or to tune the external capacitor Cext in dependence on characteristics of the cell 100 to which it is coupled. Variation of the external capacitor Cext may be varied using one or more switch networks and or capacitor multipliers, as is known in the art.

To determining a value for the series capacitor Cs for a solid-contact ISE, an analytical approach may be taken that balances the need for the external capacitor Cext to dominate overall system capacitance whilst ensuring desired performance characteristics discussed above.

The total capacitance CT when an external series capacitor Cs is added as shown in FIG. 8 is given by:

$$\frac{1}{{C}_{T}} = \frac{1}{{C}_{D L}} + \frac{1}{{C}_{e x t}}$$

Thus, to ensure the external capacitor Cext dominates the overall capacitance, the value of the external capacitor Cext should be significantly smaller than the double layer capacitance CDL, for example an order of magnitude smaller, or a tenth of the double layer capacitance CDL. This ensures the total capacitance CT is primarily determined by the external capacitor Cext, i.e. CT=Cext. The double layer capacitance CDL may be determined from equivalent circuit model (ECM) fitting of an EIS measurement.

The response time of the circuitry in FIG. 7 is determined by the RC time constant:

$$τ = R \cdot {C}_{T}$$

Where R is the membrane resistance of the cell 100 associated with the ISM 104. A smaller external capacitance Cext results in a smaller total capacitance CT, leading to shorter response time. Sensitivity, expressed as the slope of charge vs ion activity, is directly proportional to the total capacitance CT. Therefore, the size of the external capacitor Cext should be chosen as a trade-off between response time and sensitivity.

As noted above, an ISE should ideally behave as a capacitor to ensure high sensitivity, stability, and precision in ion-selective measurements. In capacitive behaviour, charge storage occurs through the formation of an electrical double layer at the interface between the solid-contact material and the ion-selective membrane, rather than through Faradaic (redox) reactions. This non-Faradaic process leads to quick and reversible charge accumulation and dissipation, which is essential for the rapid response times needed in dynamic analytical applications. Capacitive behaviour minimises potential drift, as there are no ongoing redox reactions to alter the baseline potential over time. Additionally, capacitive ISEs exhibit less noise and greater signal stability, allowing for more accurate and reproducible measurements. Achieving this ideal capacitive behaviour involves careful material selection and electrode design to enhance the capacitive properties and suppress Faradaic processes, ultimately leading to superior sensor performance.

In the embodiments described above with reference to FIGS. 3 to 5, the measurement circuitry 302 is configured to apply an AC stimulus via the series capacitor Cs and measure an AC response at the same node at which the AC stimulus is applied. In other embodiments, the response to the AC stimulus may be measured at the working electrode WE of the cell 100 itself, rather than via the series capacitor Cs.

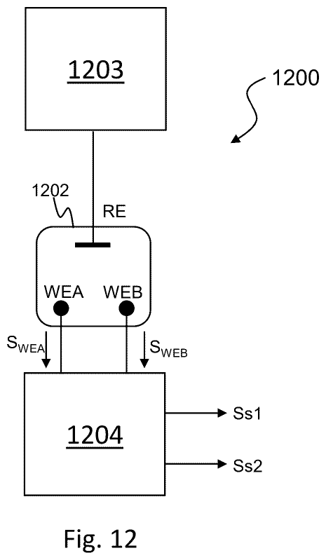

FIG. 9 is a schematic diagram of an example implementation of circuitry 900 for characterising the electrochemical cell 100 according to embodiments of the present disclosure.

The circuitry 900 comprises the series capacitor Cs and measurement circuitry 802. The series capacitor Cs is coupled between the working electrode WE of the cell 100 and an input node NI. The measurement circuitry 902 comprises an input coupled to the working electrode WE and an output configured to output a sense signal Ss which is proportional to the sense current IS at the working electrode WE.

Like the circuitry 300 of FIGS. 3 to 5, the provision of the series capacitor Cs provides a store of charge for the cell 100 which minimizes the effect of Faradaic (redox) reactions, thereby reducing drift. To probe the cell 100, a drive voltage Vd is applied at the input node NI which comprises a DC bias voltage Vbias together with an AC stimulus Vac. The response of the cell 100 to this stimulus, which will be present in a sense current Is flowing from the working electrode WE is manifested in the sense signal Ss output from the measurement circuitry 902.

The measurement circuitry 902 may be implemented as a high input impedance buffer amplifier, an example of which is shown in FIG. 10.

FIG. 10 illustrates an example implementation of the measurement circuitry 902 comprising an amplifier 1002 and an input impedance Zin. A non-inverting input of the amplifier 1002 is coupled to the working electrode WE of the cell 100. The input impedance Zin is coupled between the non-inverting input of the amplifier 1002 and a reference voltage (in this case ground). An inverting input and output of the amplifier 1002 are coupled together. Thus, the measurement circuitry 902 is configured as a high input impedance buffer amplifier which buffers the sense voltage Vs across the cell 100 to the output of the measurement circuitry 902 manifested as an output voltage Vo.

Optionally, the measurement circuitry 902 may further comprise a reset switch S1 coupled between a reset node NR and the reference voltage (in this case ground). The reset node NR is coupled to the non-inverting input of the amplifier 1002. Thus, when the reset switch S1 is closed, the input impedance Zin is bypassed, and a known reference voltage may be applied at the reset node NR. The switch S1 may be controlled to reset the reset node NR periodically or in response to one or more external signals. For example, the reset node NR may be reset on determination of a noise condition in the output voltage Vo, such as there being too much noise in the output voltage Vo or a determination that the output voltage Vo inaccurately approximates the sensor voltage Vs.

FIG. 11 is a schematic diagram showing a further example implementation of the circuitry 900 of FIG. 9. In this example, the circuitry 900 comprises measurement circuitry 1102, drive circuitry 1104, and the series capacitor Cs. In this example, the circuitry 900 is configured to receive a digital signal Sac to be converted into the drive voltage Vd and is configured to output the sense signal Ss in the digital domain as a digital sense signal Ds. In this example, the external capacitor Cext is provided external to the circuitry 900, which may itself be implemented on a single integrated circuit.

The measurement circuitry 1102 comprises the amplifier 1002 and input impedance Zin in a similar arrangement to that shown in FIG. 10. In addition, the measurement circuitry 1102 comprises an analog-to-digital converter (ADC) 1106 configured to convert the sense signal (Vo) to a digital output signal Do which is output from the circuitry 900 for downstream processing.

The drive circuitry 1104 may comprise an adder 1108 and a digital to analog converter (DAC) 1110. A digital AC signal Sac is provided to the adder 1108 which combines this signal in the digital domain with a DC bias signal Sbias. The combined digital drive signal Sd is then provided to the DAC 1110 where it is converted to an analog voltage Vd which is applied to the series capacitor Cs to be injected into the cell 100. The measurement circuitry 1102 is then configured to output a digital output signal Do which is proportional to the sense current Is at the working electrode WE of the cell 100. To measure the impedance of the cell 100, the current Is is applied indirectly via the voltage Vd output from the DAC, The voltage Vs is then measured.

An advantage of the circuitry 900 of FIGS. 8 to 10 is that both DC and AC components of the sense current Is can be derived by the measurement circuitry 902, since measurement circuitry is coupled directly to the working electrode WE. It will be appreciated, however, that the more that redox reactions are suppressed in the cell 100, the lower the DC component present in the sense signal. As such, the AC component of the sense signal, induced by the AC stimulus Vac, is likely to be less noisy and therefore more useful in inferring analyte concentration in the cell 100.

With that in mind, signals derived from the working electrode WE which comprise both DC and AC measurement components may be used to improve measurements of analyte concentration in the cell 100. For example, the sense signal Ss, or digital signal Do may be processed to obtain both the AC component and DC component, which may in turn be fused to obtain a more robust estimate of analyte concentration.

Additionally, or alternatively, AC measurement may be performed periodically, in dependence either on time (i.e. a fixed period in which AC measurement is performed) or in dependence of an event (i.e. in response to some event, an AC measurement may be performed). Example of such events may be, for example, a determination that a DC level has changed by more than a predetermined amount over a certain period of time.

The circuitry 900 described above may be implemented as part of a single integrated circuit (IC) or split across multiple separate ICs. For example, in the example shown in FIG. 10, all of the circuitry 900 may implemented on a single IC. Alternatively, components operating in the analog domain may be implemented on one IC, whilst the ADC 1006, DAC 1010 and adder 1008 may be implemented on a separate IC of plurality of ICs. The series capacitor Cs may be packaged with one or more components of the circuitry 900 or alternatively with the cell 100.

Embodiments are described above with reference to the cell 100 comprising two electrodes (e.g. a working electrode WE and a reference electrode RE). Embodiments of the disclosure are not, however, limited to having cells having two electrodes. Any of the embodiments described herein may be modified for three electrode cells comprising a working electrode WE, counter electrode CE, and a reference electrode RE.

Additionally, the concepts described herein are particularly applicable to cells comprising multiple working electrodes or multiple counter electrodes. In doing so, such sensors may either be providing redundancy or enabling the sensing of multiple analytes in a single chip. This may be particularly advantageous in applications such as continuous glucose monitoring, where it may be desirable to measure concentrations of several analytes including but not limited to two or more of glucose, ketones, oxygen, lactate, and the like. Moreover, the measurement circuits described herein may be configurable in different configurations for different types of measurements. Such measurements may be of the same or different cells or electrodes.

FIG. 12 illustrates an example circuit 1200. In the circuit 1200, an electrochemical cell 1202 is shown comprising first and second working electrode WEA, WEB and a reference electrode RE. Each of the first and second working electrodes WEA, WEB may comprise an ISE. A drive circuit 1203 is provided to apply a stimulus or DC bias to the reference electrode RE. A measurement circuit 1204 is provided which is configured to output a first sense signal Ss1 based on a signal S_{WEA} derived from the first working electrode WEA and output a second sense signal Ss2 based on a signal S_{WEB} derived from the second working electrode WEB. The first and second sense signal Ss1, Ss2 may be in the digital or analog domain. The measurement circuit 1204 may, for example, comprise two processing channels, each processing channel implementing the circuitry 300, 800 described herein. Alternatively, various components of the circuitry 300, 800 described herein may be shared between the two processing channels, e.g., through multiplexing or similar known techniques.

Embodiments of the present disclosure are described with reference to the example electrochemical cell 100. It will be appreciated, however, that the techniques and apparatus described herein may be used in conjunction with any conceivable electrochemical system, including but not limited to electrochemical cells comprising at least two electrodes (e.g. two or more of a counter electrode CE, a working electrode WE and a reference electrode RE), or electrochemical cells with more than three electrodes (e.g. two or more counter electrodes and/or two or more working electrodes). Electrodes of the electrochemical cells described herein may also be referred to as anodes and/or cathodes as is conventional in the field of electrical batteries.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus, the code may comprise conventional program code or microcode or, for example code for setting up or controlling an ASIC or FPGA. The code may also comprise code for dynamically configuring re-configurable apparatus such as re-programmable logic gate arrays. Similarly, the code may comprise code for a hardware description language such as Verilog TM or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re) programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. Circuitry for determining a characteristic of an electrochemical cell having a first electrode and a second electrode, the circuitry comprising:
a first capacitor node and a second capacitor node for coupling of a series capacitor therebetween, the first capacitor node for coupling to the working electrode;
drive circuitry coupled to the second capacitor node, the drive circuitry configured to apply a first time-varying stimulus to the first electrode via the series capacitor;
measurement circuitry configured to determine a sense signal derived from a sense current at the first electrode and output the sense signal at an output of the measurement circuitry; and
processing circuitry configured to determine a characteristic of the electrochemical cell based on the sense signal.

2. Circuitry of claim 1, wherein the characteristic of the electrochemical cell comprises one or more of:
an impedance; and
an analyte concentration.

3. Circuitry of claim 1, wherein the processing circuitry comprises:
a subtractor configured to subtract the time-varying stimulus from the sense signal and output an intermediate sense signal; and
compensation circuitry configured to apply compensation to the intermediate sense signal based on a characteristic of the series capacitor and output a compensated sense signal.

4. Circuitry of claim 3, wherein applying compensation comprises differentiating the intermediate sense signal.

5. Circuitry of claim 1, wherein the measurement circuitry comprises:
a first input coupled to the second capacitor node; and
a second input,
wherein the drive circuitry is configured to apply the first time-varying stimulus at the second input.

6. Circuitry of claim 5, wherein the measurement circuitry comprises a transimpedance amplifier, TIA, comprising:
an op-amp, wherein the first input comprises an inverting input of the op-amp, the second input comprises a non-inverting input of the op-amp, and the output comprises an output of the op-amp; and
a feedback impedance coupled between the output and the first input.

7. Circuitry of claim 6, wherein the drive circuitry is configured to apply a bias voltage at the second input, the bias voltage set to half a supply voltage of the TIA.

8. Circuitry of claim 5, wherein the measurement circuitry comprises a current conveyor, CC, wherein the first input is an X input of the CC, the second input is a Y input of the CC, and the output is a Z output of the CC.

9. Circuitry of claim 1, wherein:
the measurement circuitry comprises:
a first input coupled to the first capacitor node, the sense current measured at the first capacitor node.

10. (canceled)

11. Circuitry of claim 9, wherein the measurement circuitry comprises:
an amplifier having a first amplifier input and an amplifier output, the amplifier input coupled to the first input of the measurement circuitry; and
an impedance coupled between the first amplifier input and a reference voltage.

12. Circuitry of claim 11, wherein the amplifier comprises a second amplifier input, the second amplifier input coupled to the amplifier output.

13. Circuitry of claim 11, wherein the measurement circuitry further comprises:
a switch coupled between the first amplifier input and the reference voltage, the switch configured to selectively bypass the impedance.

14. Circuitry of claim 9, wherein the processing circuitry is configured to:
determine a first value of the characteristic of the cell based on a DC component of the sense signal;
determine a second value of the characteristic of the cell based on an AC component of the sense signal.

15. Circuitry of claim 14, wherein determining the characteristic of the cell comprises fusing the first and second values.

16. Circuitry of claim 14, wherein the processing circuitry is configured to:
determine the second value of the characteristic based on the AC component in response to a change in the first value of the characteristics of the cell over time.

17. Circuitry of claim 14, wherein the processing circuitry is configured to determine the first value and the second value periodically, the second value being determined more often than the first value.

18. Circuitry of claim 1, wherein the processing circuitry comprises:
an analog-to-digital converter, ADC, configured to output a digital sense signal based on the sense signal.

19. Circuitry of claim 1, wherein the first electrode or the second electrode comprises an ion-selective electrode.

20. (canceled)

21. Circuitry of claim 1, further comprising the series capacitor.

22. Circuitry of claim 21, wherein the series capacitor has a capacitance less than an intrinsic capacitance of the first electrode or the second electrode.

23. Circuitry of claim 21, wherein the series capacitor has a capacitance smaller than a double-layer capacitance of the electrochemical cell.

24. Circuitry of claim 23, wherein the series capacitor has a capacitance at least an order or magnitude smaller than a double-layer capacitance of the electrochemical cell.

25. Circuitry of claim 21, wherein a capacitance of the series capacitor is variable.

26. Circuitry of claim 25, further comprising one or more switch networks of capacitor multipliers to vary the capacitance of the series capacitor.

27. An electrochemical sensor, comprising:
the circuitry of claim 1; and
the electrochemical cell.

28.-29. (canceled)

30. The electrochemical sensor
of claim 27
, wherein the first electrode is a first ion selective electrode, the second electrode is a reference electrode, and the electrochemical cell further comprises a second ion selective electrode.

31. (canceled)

32. An electronic device comprising the circuitry of claim 1, wherein the electronic device comprises one of an analyte monitoring device or an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

33. A method of determining a characteristic of an electrochemical cell having a first electrode and a second electrode, the method comprising:
applying a first time-varying stimulus to the first electrode via a series capacitor;
measuring a sense current derived from the first electrode, the sense current induced by the first time-varying stimulus;
determining a sense signal based on the measured sense current; and
determining a characteristic of the electrochemical cell based on the sense signal.
